(19) United States
(12) Patent Application Publication
(10) Pub. No.: US 2019/0157222 A1
(43) Pub. Date: May 23, 2019

(54) PACKAGE WITH ISOLATION STRUCTURE

(71) Applicant: NXP USA, Inc., Austin, TX (US)

(72) Inventors: Nishant LAKHERA, Austin, TX (US); Andrew Jefferson MAWER, Austin, TX (US); Akhilesh Kumar SINGH, Austin, TX (US); Navas Khan ORATTI KALANDAR, Austin, TX (US)

(21) Appl. No.: 15/818,004

(22) Filed: Nov. 20, 2017

(51) Int. Cl. H01L 23/66; H01L 23/00; H01L 21/78

(52) U.S. Cl. CPC H01L 23/66; H01L 23/3114; H01L 24/13; H01L 24/32; H01L 24/11; H01L 24/27; H01L 21/78; H01L 24/95; H01L 24/73; H01L 24/92; H01L 2224/02373; H01L 2924/2064; H01L 2924/20641; H01L 2224/0231; H01L 2223/6627; H01L 2224/0401; H01L 2224/13024; H01L 24/14; H01L 2224/14131; H01L 2224/16227; H01L 2224/32225; H01L 2224/30179; H01L 2224/73103; H01L 2224/73104; H01L 2224/73203; H01L 2224/73204; H01L 2224/92225; H01L 2224/83007; H01L 2224/27013; H01L 24/83; H01L 24/81; H01L 24/16; H01L 24/05

(57) ABSTRACT

Embodiments are provided herein for a packaged semiconductor device that includes a semiconductor die; a redistribution layer (RDL) structure on an active side of the semiconductor die, the RDL structure including a plurality of contact pads on an outer surface of the RDL structure; a plurality of external connections attached to the plurality of contact pads; and an isolation structure on the outer surface of the RDL structure around one or more contact pads of the plurality of contact pads, wherein a height of the isolation structure is at least two thirds of a height of the external connections.

### BACKGROUND

### Field

This disclosure relates generally to semiconductor packages, and more specifically, to semiconductor packages having an isolation structure to protect connections.

### Related Art

Semiconductor packages may be attached to printed circuit boards (PCBs) by a number of solder joints, such as solder balls arranged in a ball grid array (BGA). Typically, the coefficient of thermal expansion (CTE) of a package is different than the CTE of a PCB, where this difference creates mechanical stress on the solder joints attaching the package to the PCB. To address this issue, underfill material is usually placed around the solder joints between the package and the PCB to strengthen the attachment of the package to the PCB. The underfill material protects the solder joints by distributing various mechanical stresses away from the solder joints, such as those arising from thermal expansion, as well as from mechanical shocks or vibration. The underfill material generally minimizes breaks in the solder joints, improving the robustness of the solder joints.

### BRIEF DESCRIPTION OF THE DRAWINGS

The present invention may be better understood, and its numerous objects, features, and advantages made apparent to those skilled in the art by referencing the accompanying drawings.

FIGS. 1A, 1B, 2A, 2B, 3A, 3B, 4A, 4B, 5A, 5B, and 6 are block diagrams depicting example semiconductor packages having one or more isolation structures according to some embodiments of the present disclosure.

FIG. 7A-7F are block diagrams depicting example steps of a wafer level chip scale package (WLCSP) fabrication process for a semiconductor package having one or more isolation structures according to some embodiments of the present disclosure.

FIG. 8A-8D are block diagrams depicting example steps of a singulation and attachment process for a semiconductor package having one or more isolation structures according to some embodiments of the present disclosure.

The present invention is illustrated by way of example and is not limited by the accompanying figures, in which like references indicate similar elements, unless otherwise noted. Elements in the figures are illustrated for simplicity and clarity and have not necessarily been drawn to scale.

### DETAILED DESCRIPTION

The following sets forth a detailed description of various embodiments intended to be illustrative of the invention and should not be taken to be limiting.

### Overview

While underfill material is typically used to improve the robustness of solder joints between a package and a printed circuit board (PCB), such underfill material is a dielectric or insulating material that may cause serious performance degradation of packages in radio frequency (RF) applications, such as radar or wireless communication. For example, a solder joint (such as a solder ball or solder bump) that conveys an RF signal between the package and the PCB may experience signal degradation when the solder joint is surrounded by a dielectric material. One approach to address RF signal degradation is to avoid the use of underfill altogether and instead use an edge bond material around the edge of the package to strengthen the attachment of the package to the PCB. However, the edge bond material may similarly contact or surround (or at least partially surround) solder joints located near the edge of the package. Since RF connections are often located around the edge of the package, the use of edge bond material may still result in RF signal degradation.

The present disclosure provides a protection or isolation structure for external connections on a package, which may include solder joints, such as solder balls or solder bumps, or other conductive metal joints, such as copper pillars or copper studs. The isolation structure is formed from a dielectric or passivation material on a same side of the package having the joints. The isolation structure is laterally separated from the joints (e.g., side walls of the isolation structure do not contact the joints) and acts as a barrier between the joints and any underfill material, edge bond material, mold compound material, or other dielectric or insulating material that may be used to attach the package to the PCB or to protect the package. As a result, the isolation structure minimizes RF signal degradation.

### Example Embodiments

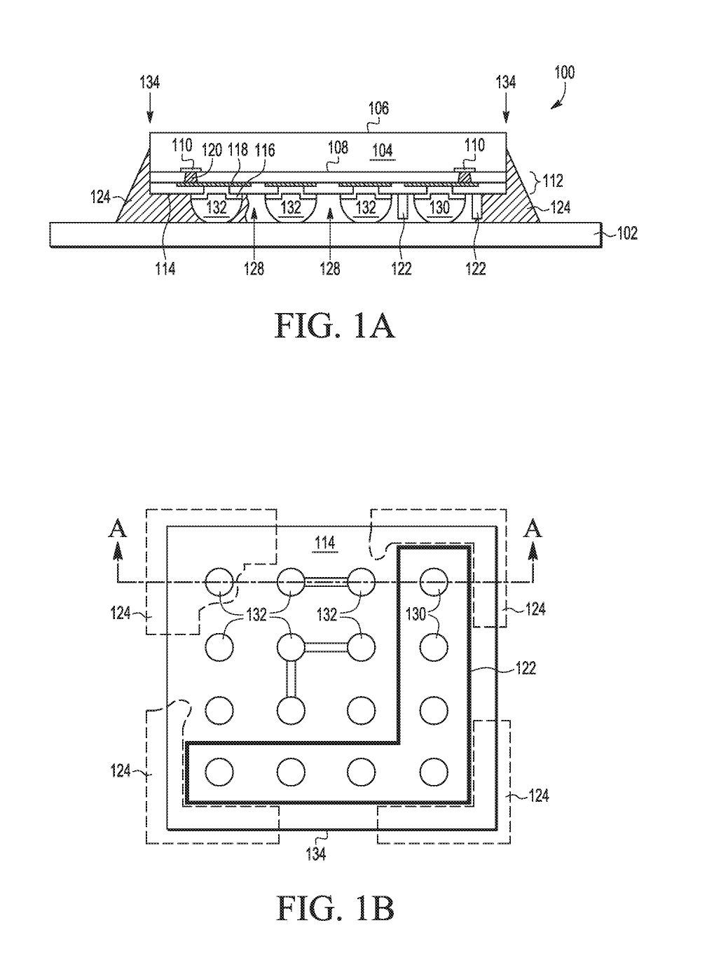

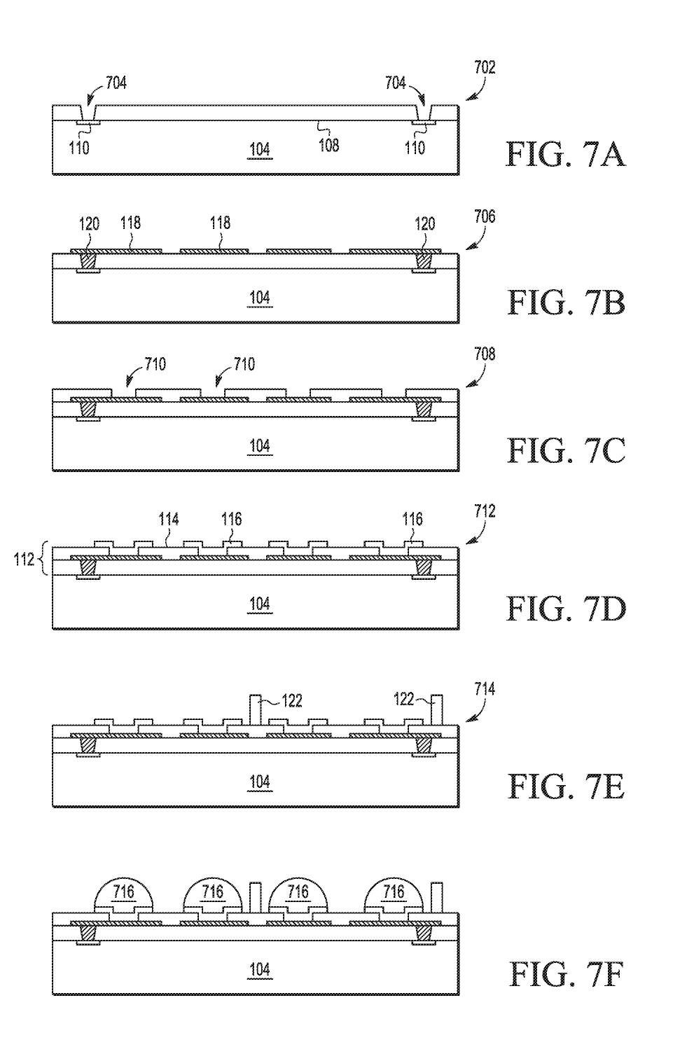

FIG. 1A shows a cross-sectional view and FIG. 1B shows a bottom-side up view of an example semiconductor package 100 (also referred to as a packaged semiconductor device 100 or simply as a package 100) having an isolation structure 122 according to the present disclosure. In the embodiment shown, package 100 is a chip scale packaging (CSP) package attached to a printed circuit board (PCB) 102. In other embodiments, package 100 may be attached to another type of suitable surface, such as a substrate, an interposer, or another package. CSP packages generally have a package footprint equal to or less than 1.2 times the die footprint, and may have a pitch equal or less than 0.8 mm. While the following figures described herein show a wafer level CSP package, the teachings of the present disclosure may also be applicable to other package types, such as a fan out wafer level packaging (FOWLP) package, a ball grid array (BGA) package, or other package types that are otherwise configured to be attached by joints (e.g., solder balls, solder bumps such as C4 bumps, copper pillars, copper studs, or other conductive metal joints) to a suitable surface (e.g., a PCB, a substrate, an interposer, or another package). An example wafer level chip scale packaging (WLCSP) fabrication process for a package that includes formation of an isolation structure is discussed below beginning with FIG. 7A.

Package 100 includes a semiconductor die 104 having a back side 106 of silicon (e.g., bulk silicon) and an opposite front side or active side 108 that includes active circuitry and a plurality of bond pads 110. In the embodiment shown, back side 106 of the die 104 also forms the back side of the package 100, although the back side of the package 100 may extend beyond the back side of the die 104 in other embodiments (e.g., embodiments with mold compound around the back side 106 of the die 104). The active circuitry may include circuitry configured to transmit or receive radio frequency (RF) signals (e.g., an RF transmitter, an RF receiver, or both in an RF transceiver). RF signals have a frequency that generally falls within a range of 20 kHz to 300 GHz. Non-RF signals have a frequency that generally falls below 20 kHz, and may also include power supply signals. Each bond pad 110 is connected to a signal line of the active circuitry that may carry either an RF signal or may carry a non-RF signal.

In some embodiments, semiconductor die 104 may be a flip chip die, having bond pads that may be attached to a suitable surface in a face-down orientation (e.g., active side facing the suitable surface). In other embodiments, semiconductor die 104 may be a wirebondable die, having bond pads that are capable of withstanding thermosonic forces during wirebonding, and usually attached to a suitable surface in a face-up orientation (e.g., back side facing the suitable surface). Package 100 also has an outer perimeter or footprint 134 at the lateral edges of the package 100, where the lateral edges of the package 100 are perpendicular to the active side 108 (as well as the back side 106) of the die 104. In the embodiment shown, lateral edges of the die 104 form the lateral edges of the package 100, although the lateral edges of the package 100 may extend beyond the lateral edges of the die 104 in other embodiments (e.g., FOWLP with mold compound around the lateral edges of the die 104).

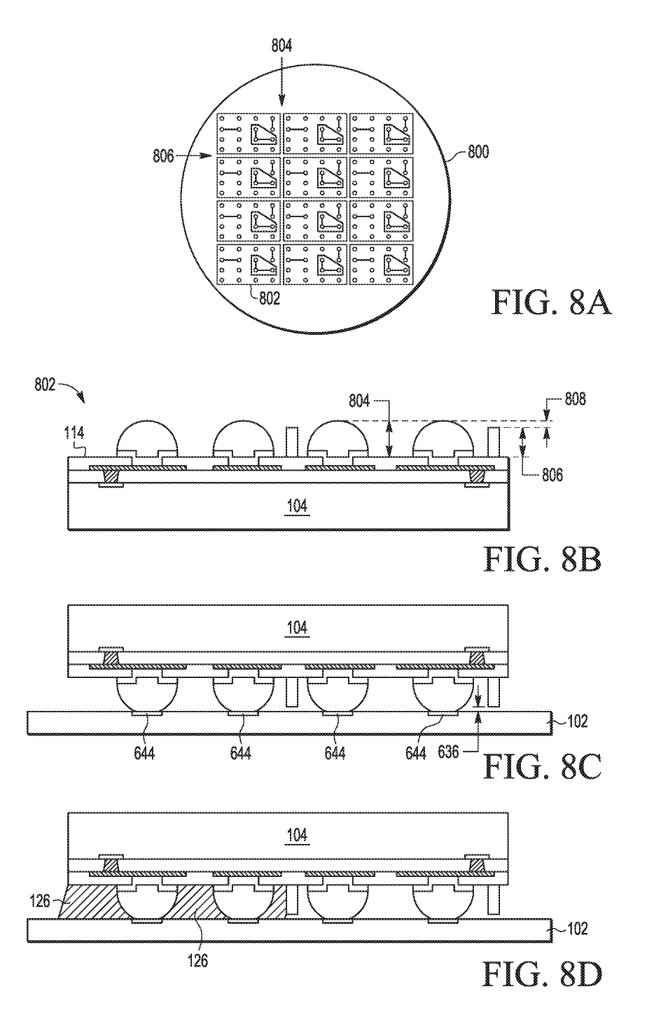

Semiconductor die 104 may be singulated from a semiconductor wafer (shown in FIG. 8A), which can be any semiconductor material or combinations of materials, such as gallium arsenide, silicon germanium, silicon-on-insulator (SOI), silicon, monocrystalline silicon, the like, and combinations of the above. Such a semiconductor die includes active circuitry, which may include integrated circuit components that are active when the die is powered. The active circuitry is formed on the semiconductor wafer using a sequence of numerous process steps applied to semiconductor wafer, including but not limited to depositing semiconductor materials including dielectric materials and metals, such as growing, oxidizing, sputtering, and conformal depositing, etching semiconductor materials, such as using a wet etchant or a dry etchant, planarizing semiconductor materials, such as performing chemical mechanical polishing or planarization, performing photolithography for patterning, including depositing and removing photolithography masks or other photoresist materials, ion implantation, annealing, and the like. In some embodiments, the active circuitry may be a combination of integrated circuit components or may be another type of microelectronic device. Examples of integrated circuit components include but are not limited to a processor, memory, logic, oscillator, analog circuitry, sensor, MEMS (microelectromechanical systems) device, a standalone discrete device such as a resistor, inductor, capacitor, diode, power transistor, and the like.

A redistribution layer (RDL) structure 112 is formed over the active side 108 of the die 104. RDL structure 112 includes a number of patterned dielectric layers and metal layers, which form routing or connection paths through the RDL structure 112. The connection paths provide electrical connections between the plurality of bond pads 110 on the die 104 and a plurality of external contact pads 116 at an outermost surface 114 of the RDL structure 112. Each connection path may include a metal filled via 120 that makes electrical contact with a respective bond pad 110, and a metal trace 118 that makes electrical contact with the metal filled via 120 at one end and makes electrical contact with a respective contact pad 116 at the other end. While the figures show simple metal traces (e.g., traces formed from a single metal layer), the patterned dielectric layers and metal layers may be repeated to create complex routing or connection paths through the RDL structure 112.

The RDL structure 112 may be formed using a sequence of process steps applied to the active side 108 of the die 104, including but not limited to depositing semiconductor materials including dielectric materials and metals, such as growing, oxidizing, sputtering, and conformal depositing, etching semiconductor materials, such as using a wet etchant or a dry etchant, performing photolithography for patterning, including depositing and removing photolithography masks or other photoresist materials, laminating, dispensing, printing, jetting, spraying, and the like. Example process steps to fabricate the RDL structure are discussed below in connection with 7A.

A plurality of external connections are respectively attached to the external contact pads 116. In the embodiment shown, the external connections are solder balls 130 and 132, where solder balls 130 are electrically connected to signal lines that carry RF signals, and solder balls 132 are electrically connected to signal lines that carry non-RF signals. Each external connection is electrically connected through contact pad 116, metal trace 118, metal filled via 120, and bond pad 110 to a respective signal line. In other embodiments, the external connections may be implemented as copper pillars or copper studs, or other suitable conductive metal joints. The plurality of external connections are also attached to landing pads 644 on the PCB 102, shown in FIG. 6, discussed below. The external connections are both electrically connected to the PCB and provide mechanical attachment of the package 100 to the PCB 102. PCB 102 includes electrically conductive features on a non-conductive substrate. PCB 102 may be a flexible type PCB using polyimide or a rigid type PCB using FR4 or BT resin.

The mechanical attachment of the package 100 to the PCB 102 may also be strengthened using an adhesive material, which is a dielectric or insulating material such as edge bond material, underfill material, mold compound material, and the like. In the embodiment shown, edge bond material 124 is placed around the perimeter 134 between the package 100 and the PCB 102, also shown in FIG. 1B in dashed outline. The edge bond material 124 may contact portions of the outermost surface 114 of RDL structure 112, and may also contact portions of the lateral edges of package 100 (which may also be lateral edges of the die 104 and lateral edges of the RDL structure 112). Examples of edge bond material 124 may include but are not limited to epoxy, resin, or low-CTE expansion filler material (e.g., silica, alumina, boron nitride, and the like) in a liquid polymer that can be cured (e.g., by heat, ultraviolet light, and the like) into a solid composite material that adheres to the package 100 and the PCB 102.

As shown on the left side of FIG. 1A, the edge bond material 124 flows under the left edge of the package 100 and makes physical contact with a lateral side of the solder ball 132. Depending on the viscosity of the adhesive material, the adhesive material may partially surround or fully surround the solder ball 132, as shown by the irregular shape of the edge bond material 124 in FIG. 1B. For simplicity's sake, the adhesive material (such as edge bond or underfill) may be shown herein as rectangular shaped having straight edges, although the edges of the adhesive material are more typically irregular shaped in actual application. As used herein, the adhesive material “partially surrounds” an external connection when it physically contacts a lateral side of the external connection, where the lateral side extends from contact pad 116 down to PCB 102 of a portion of the external connection (e.g., the adhesive material does not completely encompass the perimeter of the external connection), and “fully surrounds” an external connection when it physically contacts all lateral sides of the external connection (e.g., the adhesive material completely or substantially completely encompasses the perimeter of the external connection). Such contact (either partially or fully surrounding the external connection) may greatly degrade RF performance for external connections that carry RF signals.

To prevent the adhesive material from making such contact with the external connections that carry RF signals, an isolation structure is formed around the external connections that carry RF signals. In the embodiment shown, solder balls 130 carry RF signals, which are shown in FIG. 1B as located along the right and bottom edges of the package 100, and the isolation structure 122 is formed around solder balls 130. As shown in FIG. 6, the isolation structure has a lateral thickness 640 and a height 646. In some embodiments, the height 646 of the isolation structure is N times larger than the lateral thickness 640, where N is an integer that is equal to or greater than 1. This provides an isolation structure with a high aspect ratio that may fit in the spacing distance between external connections on the package 100 while also acting as a barrier between the external connections and any laterally spreading adhesive material that would degrade RF performance if such material (partially or fully) surrounded the external connections. The isolation structure should be able to withstand the capillary force of the adhesive material during the underfill or edge bonding process.

It is preferred that the height 646 of the isolation structure is less than a uniform height 648 of the external connections, where heights 646 and 648 are measured from the outer surface 114 of the RDL structure 112. In some embodiments, the height 646 of the isolation structure is at least two thirds of the (solder ball) height 648 in order to provide a sufficient lateral barrier around the majority of the solder ball from adhesive material. Since the height 646 of the isolation structure is less than the (uniform) height 648 of the external connections, a stand off height 636 is provided between a bottom surface of the isolation structure and the top surface of the PCB 102. This stand off height 636 allows the package to self-align during reflow to the PCB 102 without any interference from the isolation structure (e.g., avoids tilt of the package or other misalignment of the external connections to the landing pads 644 on the PCB 102 that may occur from the isolation structure contacting the PCB 102). Depending on the viscosity of the adhesive material, this stand off height 636 may also allow some of the adhesive material to flow under the isolation structure, shown as bleed 638.

Also shown in FIG. 6, sidewalls of the isolation structure are separated from each external connection carrying an RF signal by a minimum lateral gap distance 642 to provide an air gap around the external connection. The lateral gap distance 642 depends on the (uniform) spacing distance between the external connections and the lateral thickness 640 of the isolation structure. In some embodiments, the lateral thickness 640 may be at least half of the spacing distance between external connections.

In some embodiments, the spacing distance between the external connections may fall in a range of 30 to 250 microns for CSP or flip chip packages, depending on the size of the external connections being used. In some embodiments, lateral gap distance 642 may be at least 5 microns. In some embodiments, the lateral thickness 640 of the isolation structure may fall in a range 5 to 100 microns. In some embodiments, the height 646 of the isolation structure may fall in a range of 150 to 200 microns. In some embodiments, the stand off height 636 may fall in a range of 5 to 50 microns.

As an illustrative example, an example package that implements (solder ball) height 648 of 250 microns and a spacing distance of 200 to 250 microns may have a structure thickness 640 of 100 microns, a structure height 646 of 200 microns, a stand off height of 50 microns, and a lateral gap 642 of 50 to 75 microns on either side of the isolation structure 122.

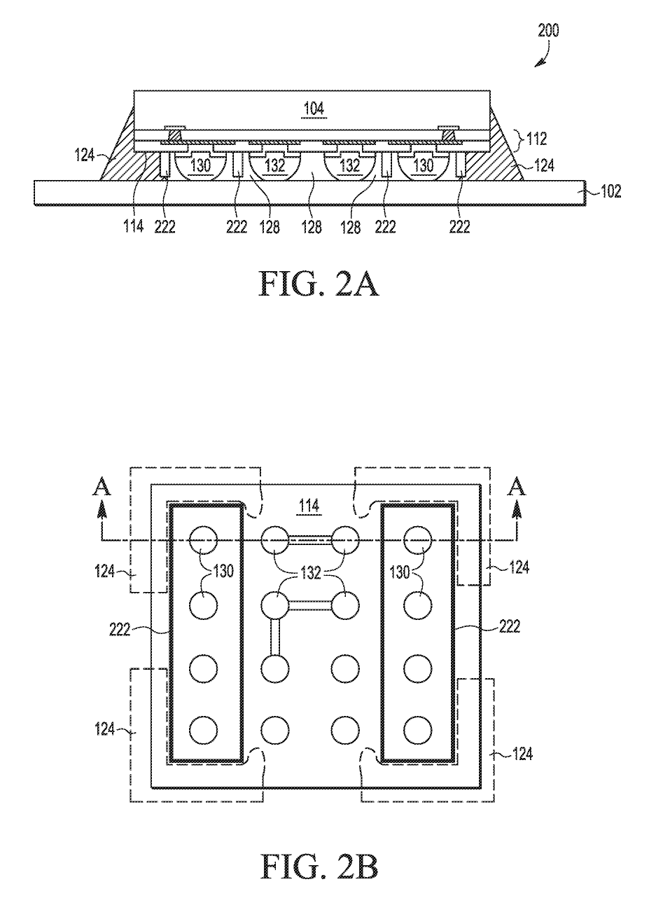

In the embodiment shown, the isolation structure 122 is formed along a closed loop path around the group of solder balls 130 (e.g., the path has an end point in a same location as its start point). In other embodiments, multiple isolation structures may be formed around multiple groups of solder balls located in different areas of the package, such as that shown in FIGS. 2A and 2B. The isolation structure may be formed from a dielectric or insulating material, such as one or more passivation (or repassivation) layers. In other embodiments, the isolation structure may be a preformed dielectric structure that is attached to the surface 114 of the package 100, such as a B-stage epoxy film (e.g., in a partially cured state) or other dielectric material that is attached to the surface 114 of the package 100 (e.g., by curing the B-stage epoxy). The isolation structure maintains an air gap around each external connection that carries an RF signal, which is beneficial for improved RF performance factors, such as noise figure, output power, and phase noise. Other examples of the isolation structure are shown in the following figures. Components having similar reference numerals correspond to components previously discussed above.

FIG. 2A shows a cross-sectional view and FIG. 2B shows a bottom-side up view of an example package 200 having two isolation structures 222 formed around groups of external connections. In the embodiment shown, the isolation structure 222 is formed around two groups of external connections, solder balls 130 near the left edge and solder balls 130 near the right edge of the package 200. Each isolation structure 222 is formed along a closed loop path around the respective group of solder balls 130. Edge bond material 124 is placed around the edges of the package 200, shown in dashed outline in FIG. 2B. Each isolation structure 222 acts as a dam to block the edge bond material 124 from contacting the external connections within each isolation structure 222.

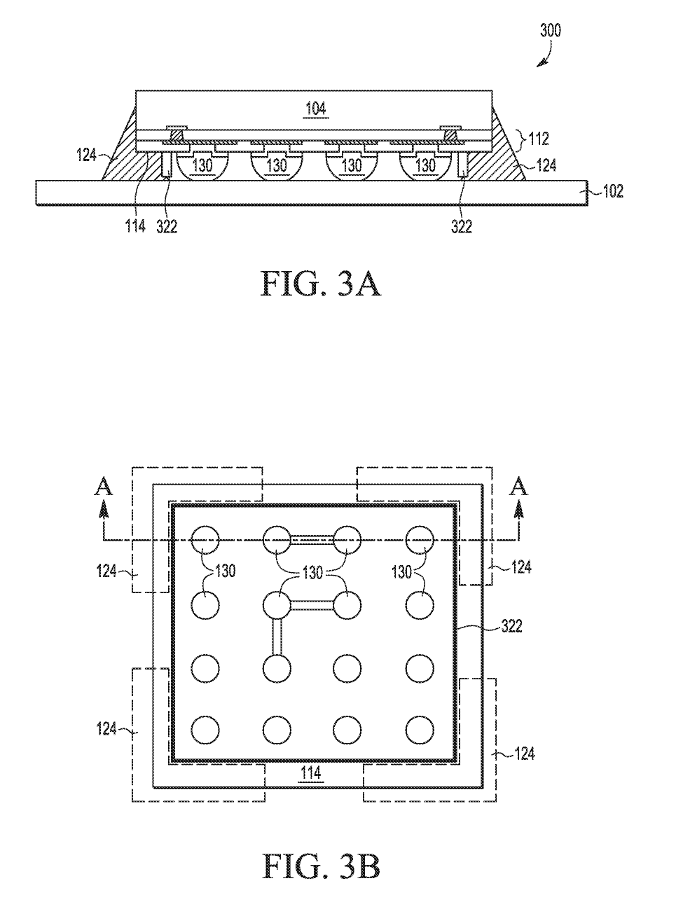

FIG. 3A shows a cross-sectional view and FIG. 3B shows a bottom-side up view of an example package 300 having an isolation structure 322. In the embodiment shown, the isolation structure 322 is formed around all external connections of the package 300, shown as solder balls 130. In some embodiments, some solder balls 130 may carry RF signals, while other solder balls 130 may carry non-RF signals. Isolation structure 322 is formed along a closed loop path around the edges of package 300. Isolation structure 322 blocks the edge bond material 124 from partially or laterally surrounding the external connections.

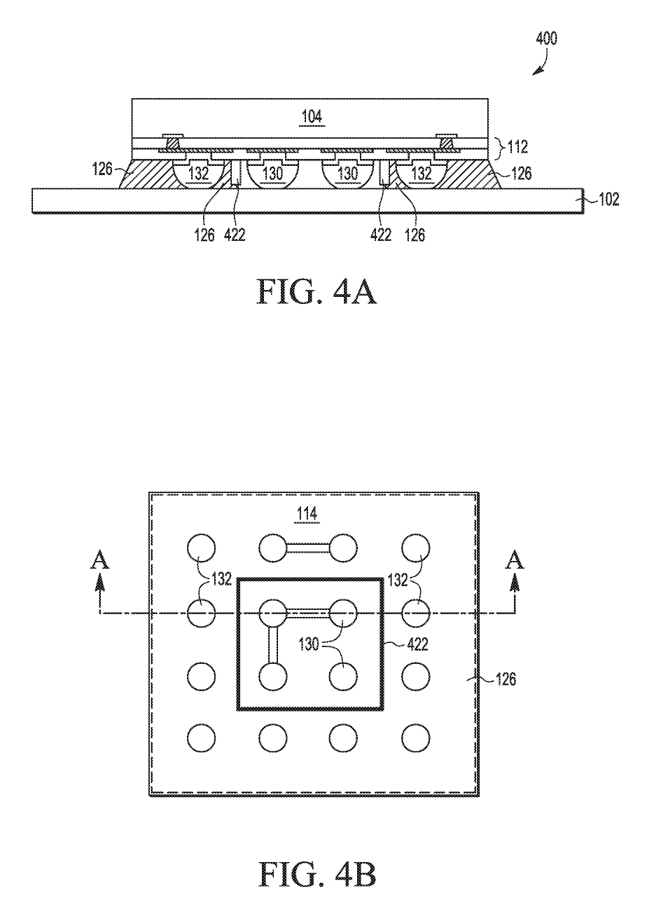

FIG. 4A shows a cross-sectional view and FIG. 4B shows a bottom-side up view of an example package 400 having an isolation structure 422. In the embodiment shown, the isolation structure 422 is formed around a group of external connections located near the center of the package 400 (rather than those located near the edge of the package). Isolation structure 422 is formed along a closed loop path around the group of external connections, or solder balls 130.

Rather than using edge bond material, underfill material 126 is placed in the space (128) around the external connections or solder balls 132 that may carry non-RF signals between package 400 and PCB 102. Underfill material 126 is a dielectric or insulating material with low CTE that adheres to the package 100 and the PCB 102. Underfill material may include but is not limited to epoxy, resin, or a low-CTE expansion filler material (e.g., silica, alumina, boron nitride, and the like) in a liquid polymer that can be cured (e.g., by heat, ultraviolet light, and the like) into a solid composite material. In some embodiments, the underfill material 126 may be mold compound material, which may be based on a biphenyl type or multi-aromatic type epoxy resin. The filler material used in underfill material generally has smaller particles than the particles used in the edge bond material to ensure the underfill material has enough viscosity to successfully flow under the package 100 and in between the metal joints without forming voids (e.g., air bubbles). The isolation structure 422 prevents the underfill material 126 from contacting the external connections within the isolation structure 422.

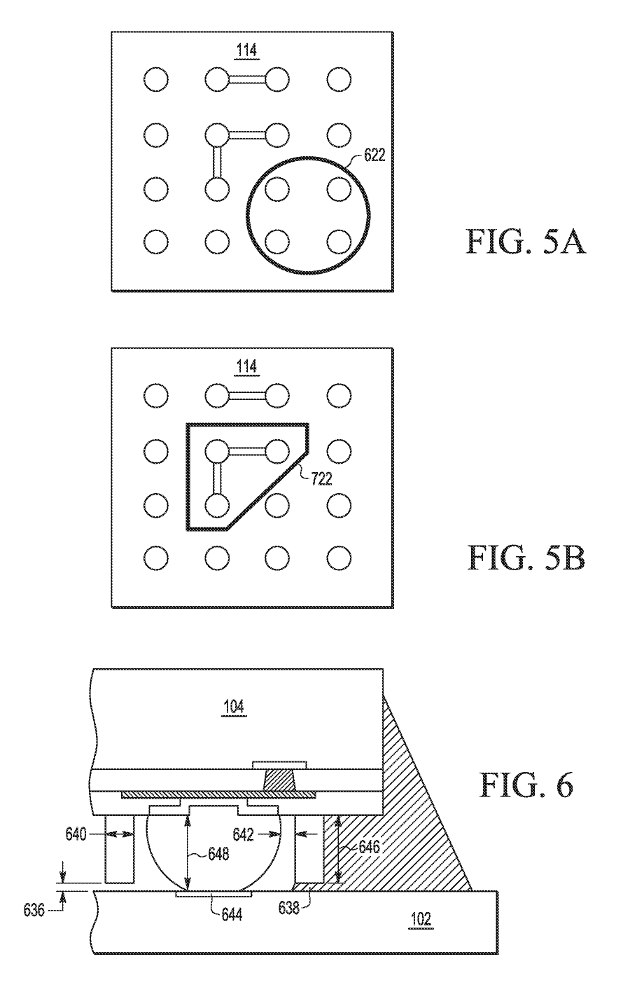

FIGS. 5A and 5B show additional examples of isolation structures, such as structure 622 that follows a circular shaped closed loop path, and isolation structure 722 that follows an irregular polygonal shaped closed loop path. In some embodiments, isolation structures may follow closed loop paths that are circular, polygonal, triangular, oblong, irregular, or other suitable closed loop shape. In some embodiments, the closed loop shape may include curved lines, angled lines, irregular lines, and the like. In some embodiments, the isolation structure may be formed around one or more external connections, which may be as few as one external connection or as many as all external connections. While the embodiments shown herein include fully populated packages, isolation structures may be implemented in packages with de-populated areas, in other embodiments. In some embodiments, the isolation structure may be formed adjacent to one or more external connections, such as near an edge of the package or near a de-populated area of the package, or may be located between one or more external connections, such as within a populated area of the package.

FIG. 7A-7F illustrates various steps of a wafer level chip scale package (WLCSP) fabrication process for a semiconductor package having one or more isolation structures. The single die 104 shown in FIG. 7A-7F may be representative of a plurality of die formed as part of a single wafer (e.g., shown in FIG. 8A), where the various steps discussed herein are implemented on all die of the wafer. The wafer may then be singulated into a plurality of packages that may be attached to a PCB or other suitable surface, as further discussed below in connection with FIG. 8A-8D.

FIG. 7A shows a cross-sectional view of an example package being fabricated after a first repassivation layer 702 has been deposited over (e.g., deposited directly on) the active side 108 of die 104 and patterned with a number of openings or vias 704 that are aligned to the bond pads 110 (e.g., the bond pads 110 are respectively exposed within the vias 704). The first repassivation layer 702 is a dielectric or insulating material, examples of which include but are not limited to polyimide, benzocyclobutene (BCB), polybenzoxazole (PBO), or other suitable polymers or dielectric materials. The first repassivation layer 702 may be conformally deposited over the active side 108 in some embodiments, spun-on over the active side 108 in other embodiments, or grown on the active side 108 in yet other embodiments. The first repassivation layer 702 may be patterned using photolithography to expose the bond pads 110 in respective vias 704.

FIG. 7B shows a cross-sectional view after a redistribution layer 706 has been deposited over (e.g., deposited directly on) a top surface of the first repassivation layer 702, including within each via 704, and patterned to form a number of metal traces 118. In the embodiments shown herein, the redistribution layer 706 fills each via 704 to form a metal filled via 120. In other embodiments, the redistribution layer 706 need not fill each via 704 and instead may only coat the sidewalls of each via 704 and the surface of the bond pad 110 within the via 704. Each metal filled via 120 that electrically contacts a bond pad is also connected to a respective metal trace 118. The redistribution layer 706 is an electrically conductive metal, examples of which include nickel, gold, copper, aluminum, or other suitable conductive metal or alloy composed of one or more suitable conductive metals.

FIG. 7C shows a cross-sectional view after a second repassivation layer 708 has been deposited over (e.g., deposited directly on) the metal traces 118 and any exposed portions of the top surface of the first repassivation layer 702, and patterned with a number of openings or vias 710. The second repassivation layer 708 is also a dielectric or insulating material, which may be the same material as the first repassivation layer 702 in some embodiments. The second repassivation layer 708 may be conformally deposited in some embodiments, spun-on in other embodiments, or grown in yet other embodiments. The second repassivation layer 708 may be patterned using photolithography to expose a top surface of the metal traces 118 within each opening or via 710. The metal traces 118 in the embodiment shown may be referred to as single level metal traces 118 (e.g., formed with a single redistribution layer).

It is noted that the steps shown in FIGS. 7B and 7C may be repeated to form multiple level traces. For example, another redistribution layer may be deposited over the second repassivation layer 708, including within each via 710, and patterned to form extended metal traces 118. Another repassivation layer may then be deposited over the extended metal traces 118, which may be patterned using photolithograph to form openings 710 in an outermost surface 114 of the resulting RDL structure 112.

FIG. 7D shows a cross-sectional view after formation of contact pads 116 in the openings 710 in the outermost surface 114 of the resulting RDL structure 112. The contact pads 116 may be formed using under bump metallization (UBM), which is a thin film stack of one or more electrically conductive metals, examples of which include but are not limited to nickel, gold, copper, aluminum, titanium, tungsten, chromium, palladium, or other suitable conductive metal or alloy composed of one or more suitable conductive metals. UBM ensures wettability of the contact pads 116 and proper adhesion of external connections (such as solder) to the contact pads 116.

FIG. 7E shows a cross-sectional view after formation of isolation structure 122. In some embodiments, a plurality of passivation layers 714 are deposited and patterned to form isolation structure 122 along a target path. In some embodiments, each passivation layer may be a photosensitive spin-coated material, or may be a dry film material in other embodiments. In some embodiments, each passivation layer may be the same material as the repassivation layers used in forming the RDL structure 112. In other embodiments, the isolation structure 122 is a preformed dielectric structure that is attached to the surface 114 of the RDL structure 112. For example, the isolation structure 122 may be formed from a B-stage epoxy that is placed on the surface 114 and cured to attach the isolation structure 122 to the package.

FIG. 7F shows a cross-sectional view after ball drop or other external connection formation process. The external connections are formed on each contact pad 116 with a uniform height. For example, the contact pads 116 may be bumped with solder material that is heated to reflow into solder balls. The lateral gap distance should also be large enough to ensure successful ball drop (e.g., the isolation structure should be placed at a distance away from a contact pad 116 to ensure that the external connection is successfully formed).

FIG. 8A shows a top-down view of an example semiconductor wafer 800 after the fabrication process in FIG. 7A-7F has been completed across every die on the wafer 800. The wafer 800 is singulated along saw lanes 804 and 806 to produce a plurality of packages 802. FIG. 8B shows a cross-sectional view of an example package 802 after singulation. It is noted that the height 806 of the isolation structure is less than the height 804 of the external connections (e.g., measured from outermost surface 114 to the peak of the external connection), which results in a height difference 808.

FIG. 8C shows a cross-sectional view after the package 802 has been attached to a PCB 102. Each external connection contacts a respective landing pad 644 on the PCB 102. After reflow, the height of the external connections is reduced. However, the height difference 808 takes into account the reduction in height after reflow and maintains a stand off height 636 between the bottom surface of the isolation structure and the top surface of the PCB. FIG. 8D shows a cross-sectional view after adhesive material is placed to strengthen the attachment of the package to the PCB 102. The underfill material 126 is prevented from contacting the external connections to be protected.

By now it should be appreciated that there has been provided an isolation structure to protect external connections on a package. The isolation structure is formed from a dielectric or passivation material that acts as a barrier between the external connections and any adhesive material that may be used to strengthen the attachment of the package to the PCB.

In one embodiment of the present disclosure, a packaged semiconductor device is provided, which includes: a semiconductor die; a redistribution layer (RDL) structure on an active side of the semiconductor die, the RDL structure including a plurality of contact pads on an outer surface of the RDL structure; a plurality of external connections attached to the plurality of contact pads; and an isolation structure on the outer surface of the RDL structure around one or more contact pads of the plurality of contact pads, wherein a height of the isolation structure is at least two thirds of a height of the external connections.

One aspect of the above embodiment provides that the one or more contact pads are connected to radio frequency (RF) signal lines of the semiconductor die.

Another aspect of the above embodiment provides that the plurality of external connections is configured to be attached to a plurality of landing pads of a printed circuit board (PCB), and an edge of the isolation structure is configured to be separated from the PCB by a stand off height.

A further aspect of the above embodiment provides that the isolation structure is configured to be a barrier between a set of external connections attached to the one or more contact pads and an adhesive material between the packaged semiconductor device and the PCB.

Another aspect of the above embodiment provides that the isolation structure includes dielectric material.

Another aspect of the above embodiment provides that the isolation structure is formed along a closed loop path around the one or more contact pads.

Another aspect of the above embodiment provides that the packaged semiconductor device further includes: another isolation structure on the outer surface of the RDL structure around another set of one or more contact pads of the plurality of contact pads.

Another aspect of the above embodiment provides that a difference between the height of the isolation structure and the height of the external connections measured from the outer surface of the RDL structure falls in a range of 5 to 50 microns.

Another aspect of the above embodiment provides that a lateral thickness of the isolation structure falls in a range of 5 to 100 microns.

Another aspect of the above embodiment provides that the height of the isolation structure is N times larger than a lateral thickness of the isolation structure, wherein N is an integer that is equal to or greater than 1.

Another aspect of the above embodiment provides that a minimum lateral distance between a sidewall of the isolation structure and a sidewall of an external connection is at least 5 microns.

In another embodiment of the present disclosure, a method for fabricating a packaged semiconductor device is provided, the method including: forming a redistribution layer (RDL) structure on an active side of a semiconductor die, the RDL structure including a plurality of contact pads on an outer surface of the RDL structure; forming an isolation structure on the outer surface of the RDL structure around one or more contact pads of the plurality of contact pads; and attaching a plurality of external connections to the plurality of contact pads, wherein a height of the isolation structure is at least two thirds of a height of the external connections.

One aspect of the above embodiment provides that the one or more contact pads are connected to radio frequency (RF) signal lines of the semiconductor die.

Another aspect of the above embodiment provides that the method further includes: singulating the semiconductor die from a wafer of semiconductor die, wherein each semiconductor die singulated from the wafer includes the isolation structure.

Another aspect of the above embodiment provides that the forming the isolation structure includes: depositing and patterning one or more layers of passivation material on the outer surface of the RDL structure along a target path around the one or more contact pads.

Another aspect of the above embodiment provides that the forming the isolation structure includes: attaching a preformed dielectric structure on the outer surface of the RDL structure around the one or more contact pads.

Another aspect of the above embodiment provides that each of the one or more contact pads within the isolation structure is connected to either a radio frequency (RF) signal line or a non-RF signal line of the semiconductor die.

Another aspect of the above embodiment provides that the plurality of external connections is configured to be attached to a plurality of landing pads of a printed circuit board (PCB), and an edge of the isolation structure is configured to be separated from the PCB by a stand off height.

Another aspect of the above embodiment provides that the isolation structure is configured to be a barrier between a set of external connections attached to the one or more contact pads and an edge bond material along a perimeter of the packaged semiconductor device.

Another aspect of the above embodiment provides that the isolation structure is configured to be a barrier between a set of external connections attached to the one or more contact pads and an underfill material between the semiconductor die and the PCB.

Because the apparatus implementing the present invention is, for the most part, composed of electronic components and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

As used herein, the terms “substantial” and “substantially” mean sufficient to achieve the stated purpose or value in a practical manner, taking into account any minor imperfections or deviations, if any, that arise from usual and expected process abnormalities that may occur during wafer or package fabrication, which are not significant for the stated purpose or value. As used herein, the term “space” indicates a void or volume in which material is absent. As used herein, the term “laterally” means in a sideways direction or a horizontal direction that is parallel to a major surface of the substrate or package.

Although the invention is described herein with reference to specific embodiments, various modifications and changes can be made without departing from the scope of the present invention as set forth in the claims below. For example, additional or fewer passivation structures 122 may be implemented in FIG. 1. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

1. A packaged semiconductor device comprising:
a package comprising: a semiconductor die, and a redistribution layer (RDL) structure on an active side of the semiconductor die;
a plurality of contact pads on an outer surface of the RDL structure;
a plurality of external connections attached to the plurality of contact pads; and
an isolation structure on the outer surface of the RDL structure around a set of at least two contact pads of the plurality of contact pads, wherein a height of the isolation structure is at least two thirds of a height of the external connections.

2. The packaged semiconductor device of claim 1, wherein the set of at least two contact pads are connected to radio frequency (RF) signal lines of the semiconductor die.

3. The packaged semiconductor device of claim 1, wherein
the plurality of external connections is configured to be attached to a plurality of landing pads of a printed circuit board (PCB), and
an edge of the isolation structure is configured to be separated from the PCB by a stand off height.

4. The packaged semiconductor device of claim 3, wherein
the isolation structure is configured to be a barrier between a set of at least two external connections attached to the set of at least two contact pads and an adhesive material between the RDL structure and the PCB.

5. The packaged semiconductor device of claim 1, wherein
the isolation structure comprises dielectric material.

6. The packaged semiconductor device of claim 1, wherein
the isolation structure is formed along a closed loop path around the set of at least two contact pads.

7. The packaged semiconductor device of claim 1, further comprising:
another isolation structure on the outer surface of the RDL structure around another set of one or more contact pads of the plurality of contact pads.

8. The packaged semiconductor device of claim 1, wherein
a difference between the height of the isolation structure and the height of the external connections measured from the outer surface of the RDL structure falls in a range of 5 to 50 microns.

9. The packaged semiconductor device of claim 1, wherein
a lateral thickness of the isolation structure falls in a range of 5 to 100 microns.

10. The packaged semiconductor device of claim 1, wherein
the height of the isolation structure is N times larger than a lateral thickness of the isolation structure, wherein N is an integer that is equal to or greater than 1.

11. The packaged semiconductor device of claim 1, wherein
a minimum lateral distance between a sidewall of the isolation structure and a sidewall of an external connection is at least 5 microns.

12-20. (canceled)

21. The packaged semiconductor device of claim 4, wherein
the adhesive material comprises edge bond material along a perimeter of the package.

22. The packaged semiconductor device of claim 4, wherein
the adhesive material comprises an underfill material between at least a portion of the RDL structure and a portion of the PCB.

23. The packaged semiconductor device of claim 4, wherein
the isolation structure is configured to block the adhesive material from contacting the set of at least two external connections.

24. The packaged semiconductor device of claim 1, wherein
each of the at least two contact pads within the isolation structure is connected to either a radio frequency (RF) signal line or a non-RF signal line of the semiconductor die.

25. The packaged semiconductor device of claim 1, wherein
the height of the isolation structure is less than the height of the external connections.

26. The packaged semiconductor device of claim 4, wherein
a single sidewall of the isolation structure facing the set of at least two external connections are separated from each of the at least two external connections by at least a minimum lateral distance.

27. The packaged semiconductor device of claim 4, wherein
the isolation structure forms a single air space surrounding the set of at least two external connections between the RDL structure and the PCB.
